(19) United States
(12) Patent Application Publication
(10) Pub. No.: US 2015/0287858 A1
(43) Pub. Date: Oct. 8, 2015

(54) PHOTOVOLTAIC MODULE INTEGRATED MOUNTING AND ELECTRONICS SYSTEMS

(71) Applicant: SunEdison LLC, Beltsville, MD (US)

(72) Inventors: Nagendra Srinivas Cherukupalli, Saratoga, CA (US); Lee Jensen, Belmont, CA (US); Magnus Asbo, Belmont, CA (US); Surya Potharaju, Belmont, CA (US); Sandeep Agarwal, Belmont, CA (US)

(21) Appl. No.: 14/243,691

(22) Filed: Apr. 2, 2014

(51) Int. Cl. H01L 31/042

(52) U.S. Cl. CPC H01L 31/0428; H01L 31/0424

(57) ABSTRACT

A system for mounting solar modules to a structure in an array includes a solar module and a connector. The solar module has a photovoltaic laminate, a frame, and a plug. The frame circumscribes the photovoltaic laminate, and includes an enclosure member extending along an edge of the photovoltaic laminate. The enclosure member has a box section that extends inward along the longitudinal length thereof. The box section is open along one end. The plug extends into the open end of the box section of the enclosure member and has energy delivery sockets that are outwardly accessible through an opening in the enclosure member. The connector is electrically connected with the energy delivery sockets and mechanically connected with the enclosure member.

### FIELD

The field relates generally to photovoltaic (PV) modules and, more specifically, to PV module mounting and installation systems and PV modules having electronics integrated into the frame.

### BACKGROUND

Photovoltaic (PV) modules (also known as solar modules) for converting solar energy into other forms of useful energy (e.g., electricity or thermal energy) include a PV laminate (also known as a solar laminate) that converts solar energy into electrical energy. The electrical energy may be used directly, converted for local use, and/or converted and transmitted to an electrical grid or another destination. A plurality of solar modules may be logically or physically grouped together to form an array of solar modules.

Solar modules generally output direct current (DC) electrical power. To properly couple such solar modules to an electrical grid, or otherwise provide alternating current (AC) power, the electrical power received from the solar modules is converted from DC to AC power using a DC/AC inverter. Some systems couple the DC output of more than one solar module to a single inverter. In other systems, an array of solar modules includes a plurality of solar modules arranged in strings of solar modules. Each string of modules is connected to a single inverter to convert the DC output of the string of solar modules to an AC output.

In still other systems, each solar module is coupled to its own inverter. Each inverter may be positioned near or on the solar module to which it is electrically coupled. A solar module including an inverter electrically coupled to the solar module is sometimes generally known as an AC PV module. A solar module that is capable of converting the energy into a consumable form and of being configurable as providing either a DC output or an AC output is needed.

Solar modules are typically mounted on a support surface by a separate frame or rack structure. This rack is also typically formed from a plurality of structural members, which may be assembled at a factory or other remote site and then transported to an installation location. The structural members may also be transported to the installation location and then assembled to form the racks on site prior to installation of the rack on the support surface. A more efficient mounting system that reduces the cost of the system and the time and labor required to install the system is also needed.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

One aspect of the present disclosure is a system for mounting solar modules to a structure in an array includes a solar module and a connector. The solar module has a photovoltaic laminate, a frame, and a plug. The frame circumscribes the photovoltaic laminate, and includes an enclosure member extending along an edge of the photovoltaic laminate. The enclosure member has a box section that extends inward along the longitudinal length thereof. The box section is open along one end. The plug extends into the open end of the box section of the enclosure member and has energy delivery sockets that are outwardly accessible through an opening in the enclosure member. The connector is electrically connected with the energy delivery sockets and mechanically connected with the enclosure member.

Another aspect of the disclosure is a solar module that includes a photovoltaic laminate, a frame, and a plug. The frame circumscribes the photovoltaic laminate, and includes an enclosure member that extends along an edge of the photovoltaic laminate. The enclosure member has a box section that extends inward along the longitudinal length thereof. The box section is open along one end. The plug extends into the open end of the box section of the enclosure member, and has energy delivery sockets that are outwardly accessible through an opening in the enclosure member.

In still another aspect, a solar module includes a photovoltaic laminate, a frame, a connector, and a printed circuit board. The frame circumscribes the photovoltaic laminate, and includes an enclosure member extending along an edge of the photovoltaic laminate. The connector board is housed within and attached to the enclosure member. The printed circuit board is removably attached to the connector board.

Another aspect of the present disclosure is a method of installing photovoltaic system including a plurality of solar modules each including a photovoltaic laminate circumscribed by a frame. The method includes configuring, by a photovoltaic system installer, each module of the plurality of solar modules as one of an alternating current (AC) module and a direct current (DC) module, and installing the plurality of solar modules at an installation site to form a photovoltaic system.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a top perspective view of a photovoltaic (PV) module;

FIG. 2 is a top perspective view of a frame of the PV module of FIG. 1;

FIG. 3 is a cross-sectional view of an edge member of the frame shown in FIG. 2 taken along the line 3-3;

FIG. 4 is a cross-sectional view of an enclosure member of the frame shown in FIG. 2 taken along the line 4-4;

FIG. 5 is an enlarged view of an enclosure member and plug shown in FIG. 1 with solar panel and edge member removed;

FIG. 6 is an enlarged side perspective view of a corner of a frame assembly of the PV module shown in FIG. 1;

FIG. 7 is an enlarged top perspective view of a cover assembly attached to the PV module shown in FIG. 1;

FIG. 8 is a bottom perspective view of the cover assembly shown in FIG. 7;

FIG. 9 is a bottom perspective view of a cover plate shown in FIG. 8;

FIG. 10 is a top perspective view of PV module shown in FIG. 1 with a cover assembly removed;

FIG. 11 is a top perspective view of PV module shown in FIG. 10 with a connector board removed;

FIG. 12 is a top perspective view of PV module shown in FIG. 11 with a potting dam and standoffs removed;

FIG. 13 is an exploded side view of a PV module array assembly;

FIG. 14 is an perspective side view of the PV module array assembly of FIG. 13;

FIG. 15 is a top perspective view of another embodiment of a photovoltaic (PV) module;

FIG. 16 is a bottom plan view of a PV module assembly; and

FIG. 17 is a side view of a rod of the PV module assembly shown in FIG. 16 installed in a snap-link bracket.

Like reference symbols in the various drawings indicate like elements.

### DETAILED DESCRIPTION

The embodiments described herein generally relate to photovoltaic (PV) or solar modules. More specifically, the embodiments described herein relate to solar modules that are configurable to provide either a DC output or an AC output.

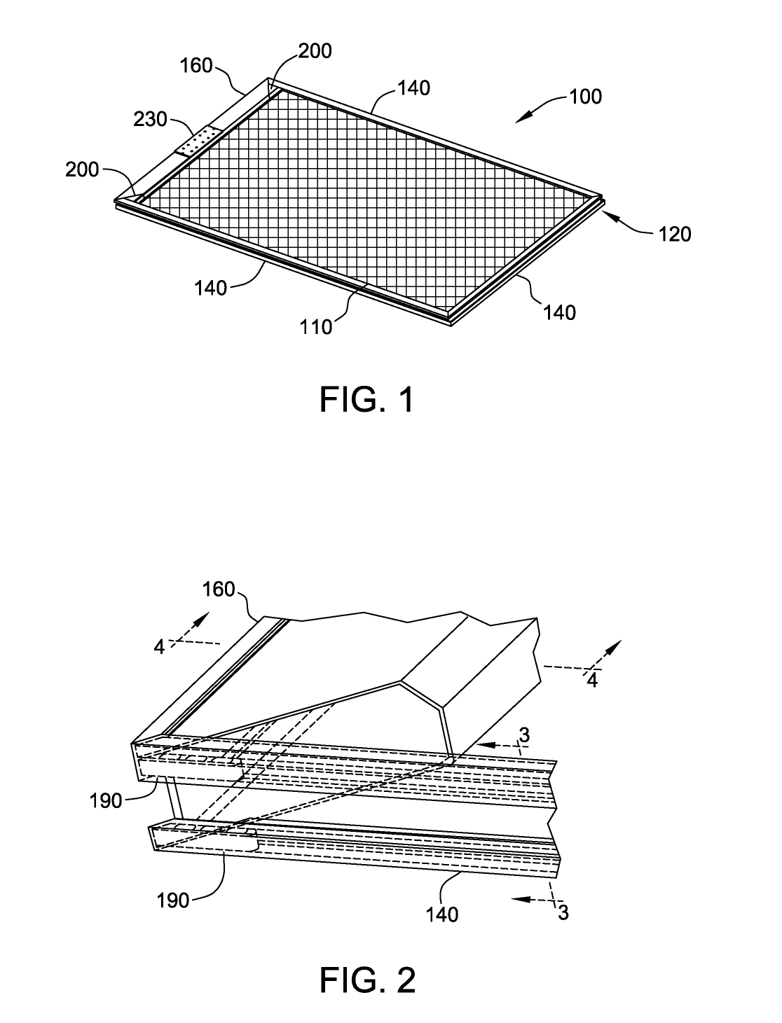

Referring initially to FIG. 1, a solar module is indicated generally at 100. The solar module 100 includes a PV laminate or solar laminate 110 and a frame assembly 120 circumscribing the solar laminate 110. In this embodiment, solar laminate 110 is rectangular in shape. In other embodiments, solar laminate 110 may have any suitable shape.

The solar laminate 110 may include several layers. The layers may include for example glass layers, non-reflective layers, electrical connection layers, n-type silicon layers, p-type silicon layers, and/or backing layers. In other embodiments, solar laminate 110 may have more or fewer, including one, layers, may have different layers, and/or may have different types of layers.

Frame 120 is coupled to solar laminate 110 and assists in protecting the edges of solar laminate 110. In this embodiment, frame 120 is constructed of four members, three edge members 140 and an enclosure member 160. One of the members 140, 160 extends along each edge of the solar laminate 110.

The frame 120 is made of extruded aluminum. More particularly, in some embodiments frame 120 is made of 6000 series anodized aluminum. In other embodiments, frame 120 may be made of any other suitable material or combination of materials providing sufficient rigidity including, for example, steel, plastic, or carbon fiber.

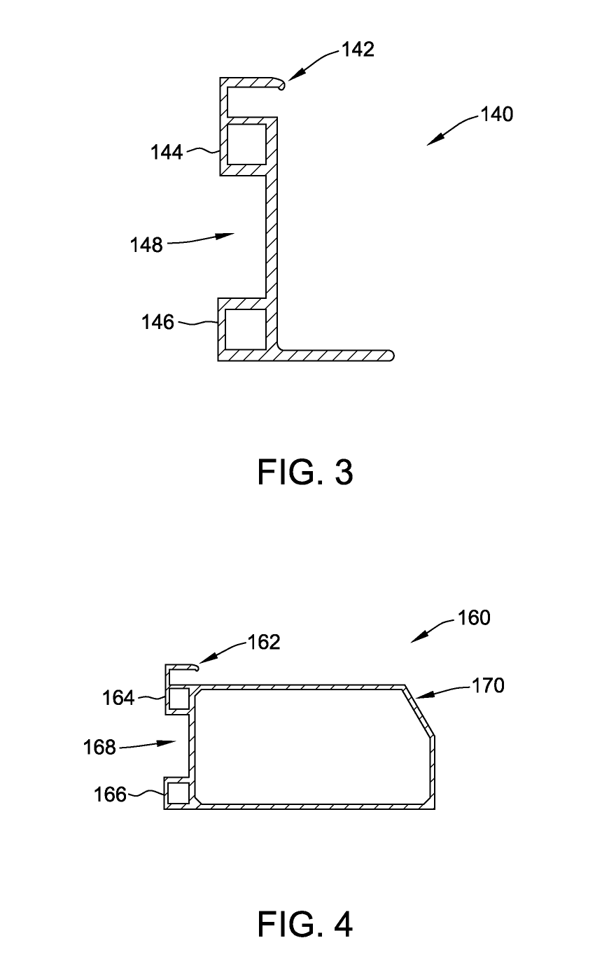

With additional reference to FIGS. 2-4, the edge member 140 has a predominantly L-shaped cross-section and the enclosure member 160 has a predominantly rectangular-shaped cross-section. Both the edge member 140 and enclosure member 160 have a lip 142, 162 for accepting and retaining the solar laminate 110 therein. Both the edge member 140 and enclosure member 160 have a top channel 144, 164 and a bottom channel 146, 166 along an outer portion thereof for accepting and retaining L-brackets 190 therein, and forming a recess 148, 168 therebetween. The L-brackets 190 hold the members 140, 160 together as an assembled frame 104. The assembled frame 104 may be secured together by fasteners, adhesive, crimping the frame components 140, 160, and 104 together, or by any other suitable assembly method(s). The L-brackets 190 may be made of metal (e.g., aluminum), plastic, or any other suitable material.

The enclosure member 160 has a box section 170 extending inward along the longitudinal length thereof. The box section 170 is open at each longitudinal end of the enclosure member 160. With specific reference to FIG. 2, each end of the edge member 140 and enclosure member 160 are cut at an angle of approximately 45°, so that when the ends of each member 140, 160 are assembled together, the frame 120 forms a rectangle, as discussed above. The angle cut on the enclosure member 160 forms a space between the box section 170 and the adjacent edge member.

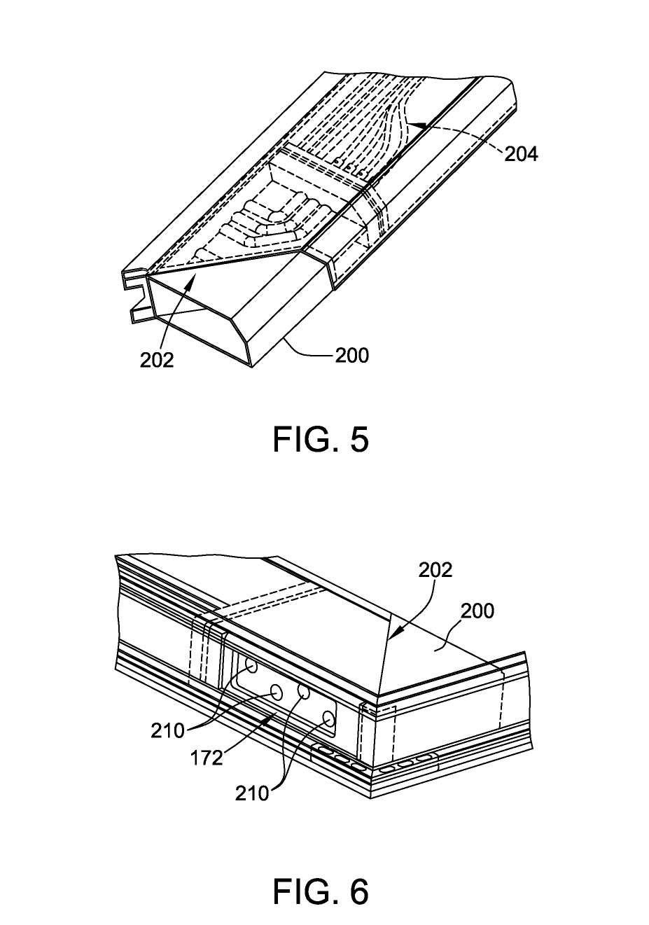

As shown in FIGS. 1, 5, and 6, a pair of plugs 200 having weather proof seals 202 extend into and close each end of the box section 170 of the enclosure member 160 to prevent water from penetrating into the interior of the box section from its end. Each plug 200 has a plurality of energy delivery sockets 210 that are outwardly accessible through an opening 172 in the recess 168 of the enclosure member 160. The plug 200 may have any number of energy delivery sockets 210, and the one or more energy delivery sockets may be arranged in any shape.

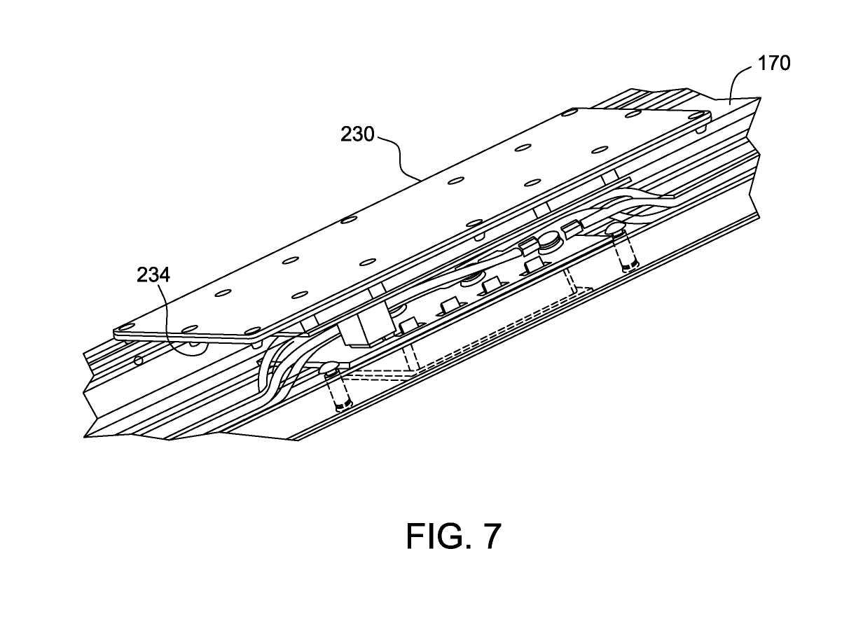

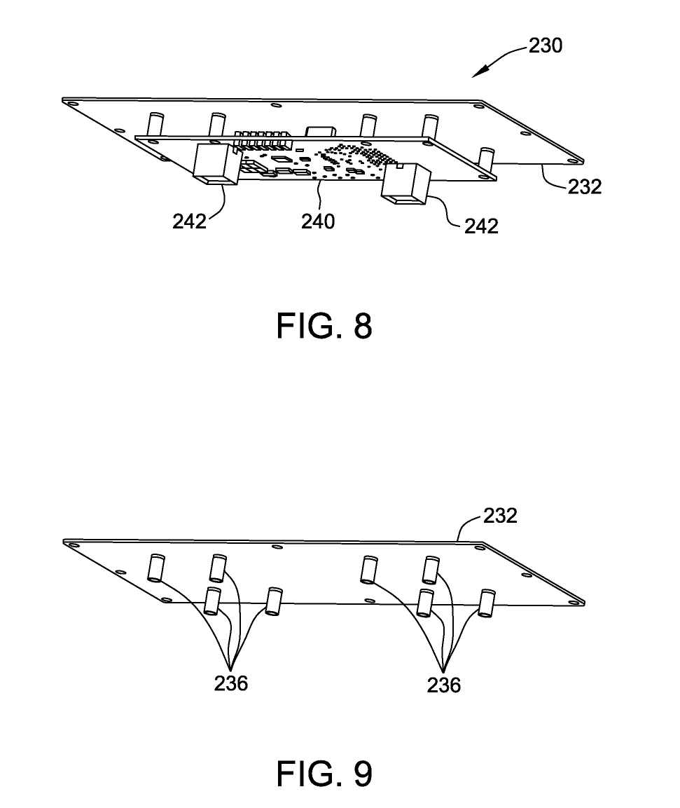

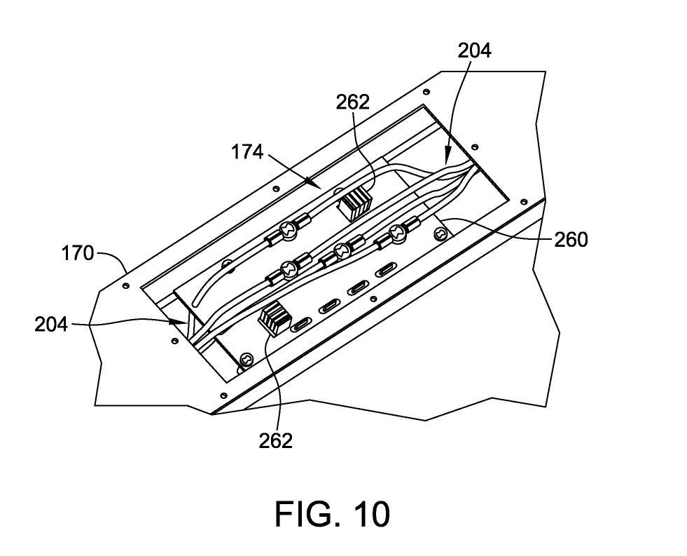

With reference to FIGS. 7-9, a cover plate assembly 230 is attached to the box section 170 of the enclosure member 160 to seal a portal 174 (Shown in FIG. 10) through an outer wall of the box section. The portal 174 provides access to the interior of the box section through a side of the box section. The cover plate assembly 230 includes a cover plate 232, an edge sealant 234 to prevent water from penetrating into the interior of the box section through portal 174, a plurality of standoffs 236, and a printed circuit board 240. The cover plate 232 may be made from aluminum or polymer or other suitable material. The standoffs 236 provide a path for heat transfer from the printed circuit board 240 to the cover plate 232, which acts as a heat sink for thermal management. The printed circuit board 240 may be a microinverter, dc-to-dc power managers/maximizers, by-pass diodes, communication modules (with and without antennas), etc. The printed circuit board 240 has at least one connector 242.

In some embodiments, the standoffs 236 are flexible to allow the printed circuit board 240 to “float” or move with respect the cover plate 232. Thus, the effect of flex or other movement of the module 100 on the printed circuit board 240 may be reduced. In other embodiments, solar modules 100 may not include standoffs for the circuit board 240. In these embodiments, heat is transferred directly from the printed circuit board 240 to the cover plate 232.

With reference to FIGS. 7 and 10-12, removal of the cover plate assembly 230 provides access, through the portal 174, to a connector board 260 located within the box section 170. The connector board 260 includes a mating connector 262 to the connector 242 on the printed circuit board 240. Together the connector 242 and mating connector 262 form a socket 270 for transferring energy between the printed circuit board 240 and the connector board 260.

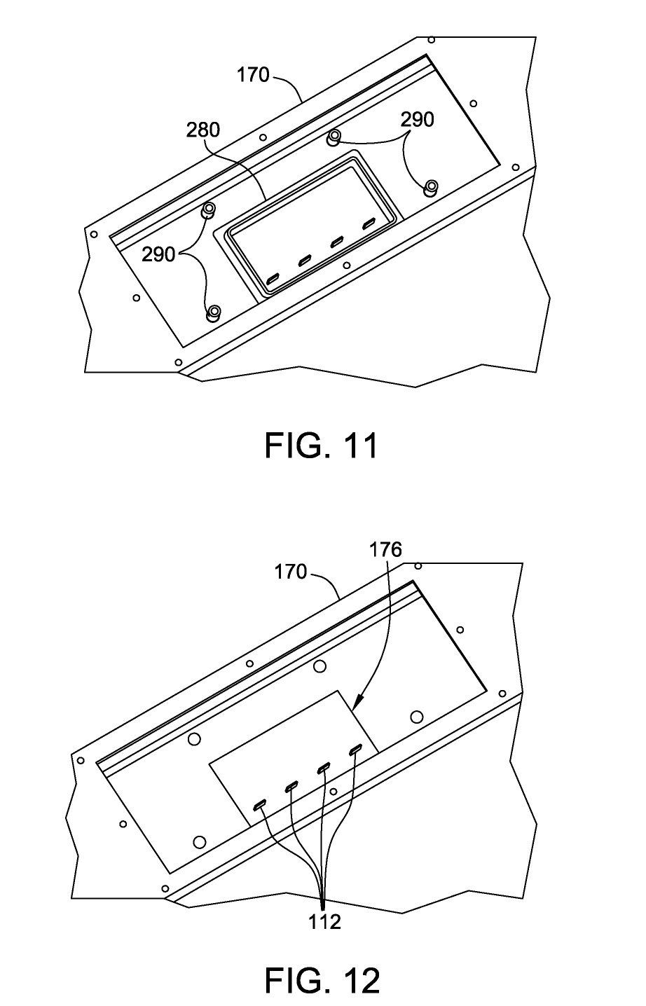

As shown in FIG. 11, power ribbons 112 from the solar laminate 110 extend directly into the box section 170 through an aperture 176 in the box section of enclosure member 160. As shown in FIG. 11, a potting dam 280 and standoffs 290 for the connector board 260 are attached to an inner surface of a wall of the box section 170. In the exemplary embodiment, the potting dam 280 is attached to both the box section 170 and the solar laminate 110 with a flexible adhesive to ensure a good seal before potting the power ribbons 112. Alternatively, the potting dam 280 may be attached to different components and/or using any other suitable attachment method. The power ribbons 112 are tabs attached with the solar laminate 110 to bring DC energy from the solar laminate to the connector board 260. From the connector board 260, the DC energy is delivered directly to the printed circuit board 240 through the socket 270. The printed circuit board 240 converts/inverts the energy from the socket 270 and delivers it to the plugs 200 via cable assembly 204.

With specific reference to FIG. 10, the power ribbons 112 may be connected with the connector board 260 by solder. The connector board 260 electrically connects the solar laminate 110 with the printed circuit board 240 and each plug 200. All of the cabling to carry output of the printed circuit board to the outside world is enclosed or embedded within the enclosure member 170 to provide weather protection for the cables. This configuration reduces overall cabling costs because the UV ratings for the cabling can be lower than that required for exposed cabling.

The cover plate assembly 530 and the printed circuit board 240 may be removed, and/or the connector board 260, may be repaired, replaced, repurposed, or changed in situ, relatively easily. For example, a DC Module may not include a printed circuit board 240, may include a by-pass diode, or may include a pass-through printed circuit board 240 (or other connection) that merely electrically connects the solar laminate to plug 200. The pass-through printed circuit board 240 or other connector may be removed and be replaced with a printed circuit board 240 including an inverter (with or without other control and/or communications circuitry) to convert the DC module to an AC module in situ. Similarly, the pass-through printed circuit board 240 or the inverter printed circuit board 240 can be removed and replaced with a managed DC printed circuit board 240 (e.g., including a DC power maximizer/manager) to convert the module 100 to a managed DC module.

Additionally, printed circuit board 240 may be removed to repair the components on the printed circuit board 240, to replace the printed circuit board 240 with another printed circuit board 240 of the same type, to upgrade the printed circuit board 240 to a newer model, and the like. Further, a variety of electronics may be integrated into the enclosure member 160, such as microinverter, dc-to-dc power maximizers, by-pass diodes, communication modules (with and without antennas). Thus, the module 100 may be configured, reconfigured, repaired, and/or upgraded at any location before installation and at the site of installation before, during, and/or after installation, without needing to remove the module 100 from its installed location. In some embodiments, the installer may detach the module 100 from its support structure (either fully or partially) to access the bottom of the module 100 to perform the reconfiguration. For example, an installer may completely detach the module 100 from its mount and turn it over, or may detach one side of the module 100 and lift the detached side to access the bottom of the module 100. Regardless of whether the module 100 needs to be removed (partially or fully) or may remain installed on a structure, the module may be repaired, reconfigured, upgraded, etc. onsite at its installed location without needing to be transported to a different location.

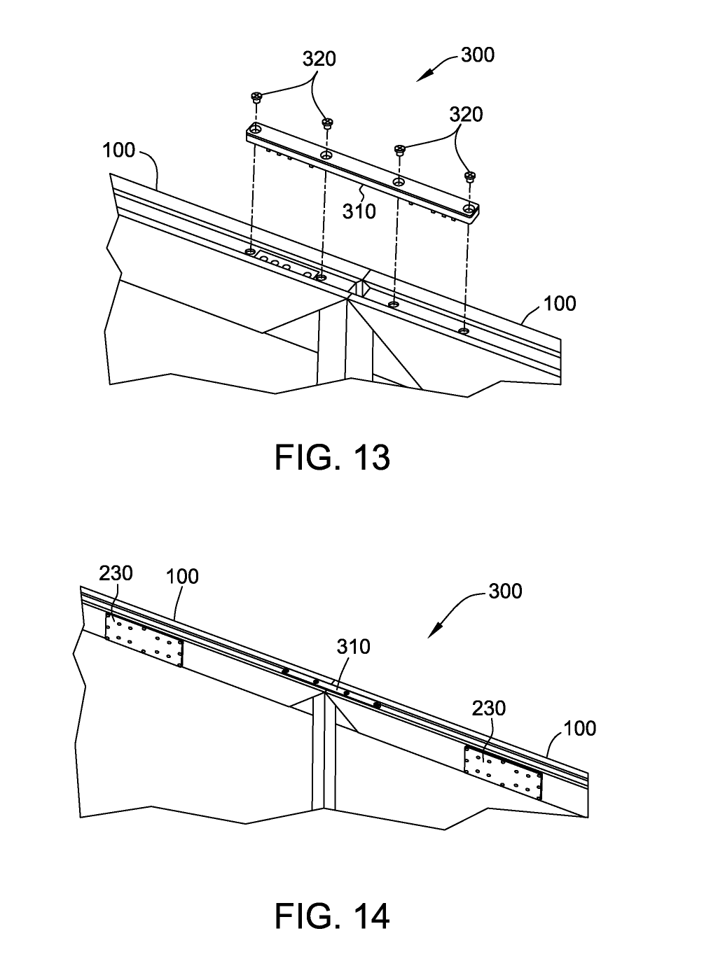

With reference to FIGS. 13 and 14, a solar array 300 is shown that includes a first and second solar module 100, a connector 310, and a plurality of fasteners 320. Connector 310 connects with a side of each solar module 100 and acts as an electromechanical connection transferring both electrical and mechanical loads between the first and second solar modules 100. Connector 310 may be installed, removed, and replaced by unfastening it from the sides of the solar modules 110, without detaching the solar modules from a mounting structure or otherwise disassembling them.

Connector 310 serves as a conduction path for the energy from one module to the next, as well as a mechanical brace to prevent modules from moving relative to each other (e.g. flopping). Grounding is embedded in the connector 310 to provide a common ground plane for connected modules 100. The connector 310 is flexible and thermally resilient to withstand and/or absorb movement caused by external forces, such as those caused by wind, rain, and snow, changing temperature from day to night, and from season to season to prevent loosening of the interconnection.

Connector 310 is attached to each solar module 100 with a pair of screws or other suitable fasteners, which prevents the connector 310 from being disconnected or spaced apart from the socket 270. The fasteners also counteract torque created by the movement of one solar module with respect to the other. Connector 310 is also substantially equivalent in width to the recess 168 in the enclosure member 160. Therefore, any movement of the first solar module 100 with respect to the second solar module 100 creates an equal and opposite reaction force against the connector 310 to help prevent further movement of the solar modules with respect to the other solar module.

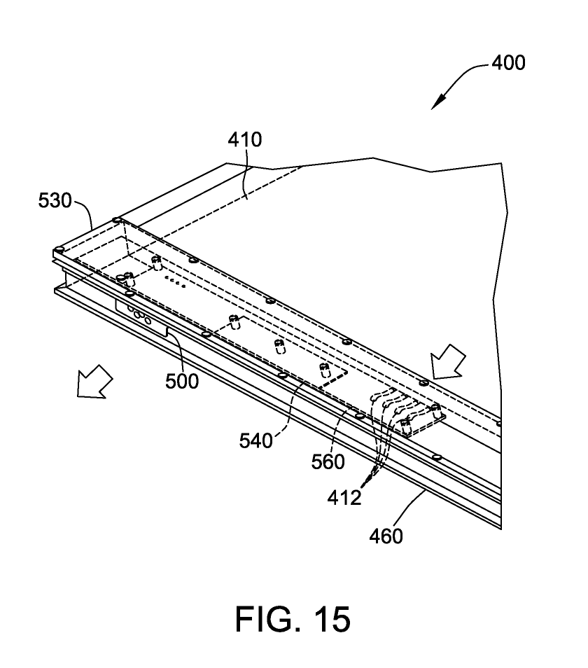

Referring to FIG. 15, another solar module 400 is shown having a cover plate assembly 530 that extends the length of the enclosure member 460. The enclosure member 460 forms a housing that has a plug 500 along one end. The plug 500 is connected directly to the connector board 560. Except as otherwise described herein, the solar module 400 is substantially the same as the solar module 100 described above.

In this embodiment, a solar laminate 410 has power ribbons 412 that are connected through spring connectors with the connector board 560. The connector board 560 is fastened to the water proof cover plate assembly 530 and housed within an enclosure member 460. As a result, the connector board 560 is removably connected with the solar module 400 through the cover plate assembly 530. In a single step, the cover plate assembly 530, the connector board 560, the plug 500, and the printed circuit board 540 may all be removed and replaced together, as a single unit, or individually. The plug 500 is similar to the plug 200 used to connect similar solar modules in a similar manner and process. Thus, one of the electronic components, connector board 560 and printed circuit board 540 and plug 500, of the solar module 400 may be removed, repaired, repurposed, or changed (e.g., between an AC module, a managed DC module, and a DC module) in situ relatively easily.

As described above, the exemplary solar modules may be configured, reconfigured, repurposed, etc. In one example method for installing a photovoltaic system, an installer begins an installation with at least one DC solar module, such as solar module 100. The DC solar module 100 includes no printed circuit board 240, includes a by-pass diode, or includes a pass through printed circuit board 240 (or other connector). The installer configures each DC module 100 as desired for the installation by installing a printed circuit board 240 with the desired components into the solar module 100. In the case of a DC solar module 100 that includes a pass through printed circuit board 240 (or other connector), the installer removes the pass through printed circuit board 240 and replaces it with the printed circuit board 240 having the desired functionality. If the DC module 100 does not include any printed circuit board 240, the installer simply installs the printed circuit board 240 with the desired functionality. The desired printed circuit board 240 is installed by replacing the DC module's cover plate assembly 230 with a cover plate assembly 230 including the printed circuit board 240 with the desired functionality. Alternatively, the installer may reconfigure the assembly 230 by removing the undesired printed circuit board 240 from the cover plate 232 and attach the desired printed circuit board 240 to the cover plate 232. The circuit board 240 installed by the installer can include a microinverter, a dc-to-dc power maximizer, a by-pass diode, a communication module, or any other desired solar modules component(s). Thus, the installer reconfigures the DC module 100 into an AC module, a DC module, a managed DC module, or any other desired type of solar module 100. The configuration of the solar module 100 may be performed by the installer at the site of the photovoltaic system installation, at the installer's shop, or at any other location. Moreover, the in some embodiments, the installer physically installs the DC modules 100 at the installation site (e.g., mounts the modules 100 to racks, trackers, etc.) before configuring the DC modules 100 to the desired functionality.

In another example method, an installed solar module, such as solar module 100, is accessed on by a technician. The technician may be an installer, repair technician, system optimizer, or any other qualified person who accesses and/or works on photovoltaic systems. The technician removes the cover plate assembly 230 from the solar module 100 at the installation site. The printed circuit board 240 and/or the connector board 260, may be configured, repaired, replaced, repurposed, or changed. While the cover plate assembly 530 is removed from the solar module 100, the technician may repair the printed circuit board 240 and/or connector board 260, or the technician may repair or replace another electrical component within the solar module. Moreover, the technician may replace the cover plate assembly 230 with another cover plate assembly 230 having a printed circuit board 240 with the same or different functionality. Thus, for example, the technician may repurpose the solar module 100 from an AC output to a DC output, change the solar module 100 from a DC output to an AC output, change an electrical component to increase the efficiency of the solar module, upgrade the module to a newer design, and the like.

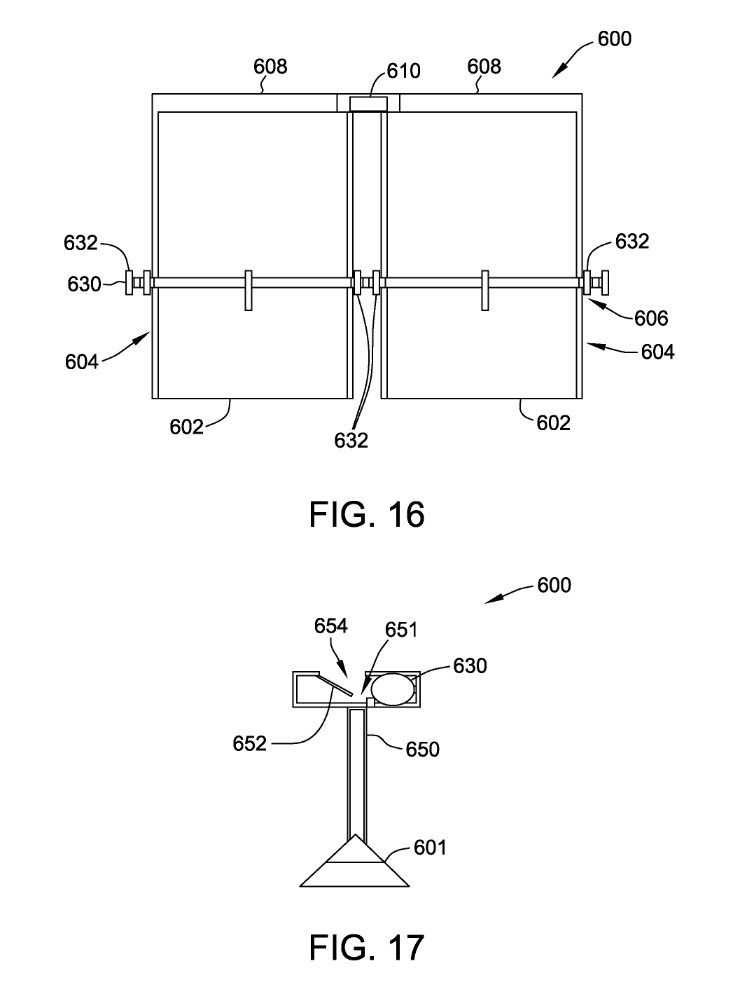

Referring to FIGS. 16 and 17, a system for mounting solar modules to a structure 601 is indicated generally at 600. The system 600 includes a first and second solar module 602, a connector 610, a rod 630, and a pair of mounts 650. As shown in FIG. 16, connector 610 is attached to each solar module 602 through the end of an enclosure member 608. As discussed above in reference to connector 310, connector 610 also provides an electromechanical connection between the first and second solar modules 602.

The rod 630 is expandable and sized to be inserted through a module hole 606 in a frame 604 of the solar module 602. The rod 630 is tapped off on each side of the frame 604 with couplers 632. The couplers 632 allow the first solar module 602 to be connected with an adjacent solar module 602. The couplers 632 help limit and/or prevent longitudinal movement of the solar module 602 with respect to the rod 630.

The mount 650 is configured to mount a module 100 to the structure 601. The mount 650 defines an interior 651 and an opening 654. The interior is configured to receive the rod 630. The opening 654 to the interior 651 is configured to permit the rod 630 to pass through the opening 654. A snap-link 652 selectively covers the opening 654 that extends through the mount 650. Snap-link 652 is selectively movable between an open position and a closed position, and is biased to the closed position by a spring. The link 652 is selectively movable between the open position that permits access to the interior through the opening 654 and a closed position that substantially covers the opening 654.

To install a solar module 602 the mount 650 is attached to the structure and the rod 630 is positioned over the snap-link 652. The snap-link 652 is moved from the closed position to the open position by pressing down on the rod 630 while it is positioned over the snap-link. The rod 630 passes through the opening 654 and into the interior 651 while the snap-link 652 is in the open position. The rod 630 is moved to a location in the interior 651 that is spaced from the snap-link 652 such that the spring biased snap-link is biased from the open position to the closed position. As a result, the rod 630 is “snapped” in place using the snap-link 652 attached to the top of the mount 650. The spring loaded snap-link 652 secures the solar module to the mount 650 without fastening hardware.

The embodiments of the solar module and method for installation described herein provide a water proof system with a lower associated cost to manufacture and to install when compared to prior systems and methods. For example, material cost is reduced through the elimination of all extraneous hardware required to extract, convert, and deliver the energy for external consumption. These embodiments do not require the diodes, pigtails, MC4s, junction-box, frame mounting hardware, or the housing for the electronics needed for typical solar module installations. Still further, the present embodiment allows the majority of parts to be made and preassembled in mass quantity.

The present embodiments also allow for a variety of electronics to be integrated into the frame of a solar module to deliver complete solutions for the residential and commercial market segments. The integration involves capturing the energy from the module directly onto a printed circuit board from the laminate that encapsulates solar cells, converting the energy into a consumable form, either power maximized AC or power maximized DC, and delivering the consumable form of energy via an integrated and frame enclosed electrical system.

The solar module and related parts may be bundled together into kits and transported to the installation site. The bundled kits reduce the area needed to transport and store the solar modules, and reduce the parts required to be tracked and assembled at the installation site. Additionally, the solar module can be installed quickly at the installation site using a reduced number of fasteners, which reduces both the installation labor and installation times.

Moreover, installers and/or system integrators may maintain an inventory of DC modules (at their shops, in their delivery/installation vehicles, or both) along with the components needed to configure the DC modules to DC modules, AC modules, managed DC modules, etc. To install a system, the installer can configure the modules as needed, rather than having to order and wait for delivery of a module, or maintain a large inventory of different, specialized solar modules.

When introducing elements of the present disclosure or the embodiments thereof, the articles “a”, “an”, “the” and “said” are intended to mean that there are one or more of the elements. The terms “comprising”, “including” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above without departing from the scope of the present disclosure, it is intended that all matter contained in the above description and shown in the accompanying drawings shall be interpreted as illustrative and not in a limiting sense.

What is claimed is:

1. A system for mounting solar modules to a structure in an array, the system comprising:
a solar module including:
a photovoltaic laminate;
a frame circumscribing the photovoltaic laminate, the frame including an enclosure member extending along an edge of the photovoltaic laminate and having a box section extending inward along the longitudinal length thereof, the box section being open along one end; and
a plug extending into the open end of the box section of the enclosure member, the plug having energy delivery sockets being outwardly accessible through an opening in the enclosure member; and
a connector electrically connected with the energy delivery sockets and mechanically connected with the enclosure member.

2. The system of claim 1, wherein no solar module wires extend outward from the box section of the enclosure member.

3. The system of claim 1, wherein the photovoltaic laminate includes power ribbons extending directly into the box section of the enclosure member.

4. The system of claim 3, wherein the power ribbons are potted to prevent water ingress around the power ribbons.

5. The system of claim 3, wherein the power ribbons are connected with a connector board located within the box section.

6. The system of claim 5, wherein the connector board is accessible in the box section through a portal in an outer wall of the box section.

7. The system of claim 5, wherein the connector board is connected with the energy delivery sockets.

8. The system of claim 5, further comprising a printed circuit board connected with the connector board.

9. The system of claim 8, wherein the printed circuit board is one of a microinverter, dc-to-dc power maximizer, by-pass diode, and a communication module.

10. The system of claim 1, the enclosure member defines a longitudinal recess having a width being substantially equivalent to a width of the connector.

11. The system of claim 1, further comprising a second solar module connected with the connector to form an array.

12. A solar module comprising:
a photovoltaic laminate;
a frame circumscribing the photovoltaic laminate, the frame including an enclosure member extending along an edge of the photovoltaic laminate and having a box section extending inward along the longitudinal length thereof, the box section being open along one end; and
a plug extending into the open end of the box section of the enclosure member, the plug having energy delivery sockets being outwardly accessible through an opening in the enclosure member.

13. The solar module of claim 12, wherein no solar module wires extend outward from the box section of the enclosure member.

14. The solar module of claim 12, wherein the photovoltaic laminate includes power ribbons extending directly into the box section of the enclosure member.

15. The solar module of claim 14, wherein the power ribbons are connected with a connector board located within the box section.

16. The solar module of claim 15, wherein the connector board is accessible in the box section through a portal in an outer wall of the box section.

17. The solar module of claim 15, wherein the connector board is connected with the energy delivery sockets.

18. The solar module of claim 15, further comprising a printed circuit board connected with the connector board.

19. The solar module of claim 18, wherein the printed circuit board is one of a microinverter, dc-to-dc power maximizer, by-pass diode, and a communication module.

20. A solar module comprising:
a photovoltaic laminate;
a frame circumscribing the photovoltaic laminate, the frame including an enclosure member extending along an edge of the photovoltaic laminate;
a connector board housed within and attached to the enclosure member;
a printed circuit board removably attached to the connector board.

21. The solar module of claim 20, wherein the printed circuit board is removable from the solar module while the connector board remains attached to the enclosure member.

22-36. (canceled)
